(19) United States
(12) Patent Application Publication
(10) Pub. No.: US 2009/0243681 A1
(43) Pub. Date: Oct. 1, 2009

(54) Embedded Source-Synchronous Clock Signals

(75) Inventors: Jared L. Zerbe, Woodside, CA (US); Aliazam Abbasfar, Mountain View, CA (US)

Correspondence Address: SILICON EDGE LAW GROUP, LLP, 6601 KOLL CENTER PARKWAY, SUITE 245, PLEASANTON, CA, 94566, US

(73) Assignee: Rambus Inc., Los Altos, CA (US)

(21) Appl. No.: 12/398,493

(22) Filed: Mar. 5, 2009

Related U.S. Application Data
(60) Provisional application No. 61/072,027, filed on Mar. 26, 2008.

(51) Int. Cl. H03L 7/00

(52) U.S. Cl. 327/163

(57) ABSTRACT

A synchronous communication system includes two transmitters that transmit respective first and second data signals that are phase offset from one another by about 90 degrees. On the receive side, a pair of extraction circuits extract a first clock signal from the first data signal and a second clock signal from the second data signal. The clock signals are offset from one another by about 90 degrees due to the phase offset of the corresponding data signals. Edges of the first clock signal are thus centered within the symbols of the second data signal, and edges of the second clock signal are centered within the symbols of the first data signal. A pair of receivers employs the first clock signal to sample the second data symbol and the second clock signal to sample the first data signal.

### FIELD

The invention relates to high-speed signaling within and between integrated circuits.

### BACKGROUND

In a typical high-speed digital communication system, a transmitter encodes some information into a series of symbols, typically binary values represented by voltage or current levels, which are conveyed to a receiver over some form of communication channel. The receiver then decodes the symbols to recover the original information. The transmitter and receiver must be synchronized for the receiver to make sense of the data. Various clocking schemes are used to this end. Typical clocking schemes include synchronous clocking, clock forwarding, and embedded clocking.

In synchronous clocking, a single clock signal is shared between the transmitter and receiver, and all symbols are transmitted and received with respect to transition of the clock signal. Synchronous clocking is relatively simple to implement, but there is a limit to how precisely a given clock signal can be distributed to multiple destinations. Synchronous clocking is therefore disfavored for high-speed systems.

Clock forwarding, also called “source-synchronous clocking,” addresses the difficulty that synchronous clocking has with matching the timing of distributed clock signals to multiple destinations. In this type of clocking, a transmitter conveying a data pattern creates and transmits to the receive device its own clock signal that is transferred along with the data. The clock and data thus traverse similar paths and incur similar delays, which produces a relatively tight timing correlation and minimal skew between the clock and data as compared with a synchronous architecture. Clock signals generally have more destinations than data signals, however, so clock and data paths exhibit different delays even when traversing otherwise similar paths. High-performance clock-forwarding schemes therefore include circuitry, either at the transmitter or receiver, that calibrates the timing of the data and clock signals to accommodate the different characteristics of clock and data lines.

In embedded clocking, data is encoded in a manner that will guarantee a certain number of transitions per unit time (i.e., a minimum transition density) and is sent without a corresponding bit-rate clock. Clock-recovery circuitry at the receiver then synchronizes a local clock signal to the data transitions and uses the resulting “locked” clock signal to sample the data. This type of clocking can be used to achieve extremely high data rates, but the clock recovery circuitry is relatively complex, area intensive, power hungry, and can take many clock cycles to reach stable frequency and phase lock after transitioning from a zero or low-power state to an active state.

### BRIEF DESCRIPTION OF THE DRAWINGS

The subject matter disclosed is illustrated by way of example, and not by way of limitation, in the figures of the accompanying drawings and in which like reference numerals refer to similar elements and in which:

FIG. 1 depicts a synchronous, digital communication system 100 that uses embedded timing information to recover received data in accordance with one embodiment.

FIG. 2 depicts an embodiment of encoder 125 of FIG. 1, an instance of which may also be used for encoder 130 of FIG. 1.

FIG. 3 depicts receiver RX0 of FIG. 1 in accordance with one embodiment.

FIG. 4 is a flowchart 400 illustrating the encoding and decoding of an arbitrary sub-word Daₙ[7:0]=11110011b using embodiments of encoder 125 and decoder RX90 of FIGS. 2 and 3, respectively.

FIG. 5 depicts an embodiment of clock extraction circuit ClkExt0 of FIG. 1, an instantiation of which may also be used for extraction circuit ClkExt90.

### DETAILED DESCRIPTION

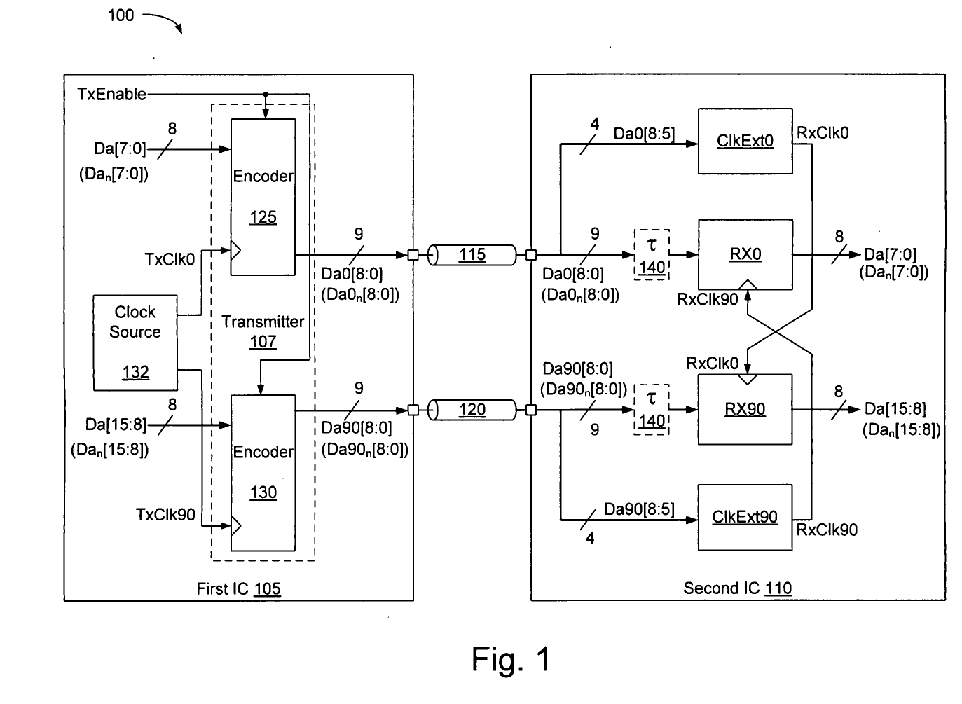

FIG. 1 depicts a synchronous, digital communication system 100 in which a first integrated circuit (IC) 105 includes a transmitter 107 that embeds timing information into conveyed data in a manner that allows receivers within a second IC 110 to extract clock signals from the data without the complex, power-hungry clock-recovery circuitry normally required for embedded-clock architectures. Furthermore, because the timing information is embedded in the data, the recovered clock signals are subject to the same delay as the data signals. This attribute of system 100 simplifies the task of correlating the clock and data timing at the receiver and enables the system to be powered-on and off rapidly, facilitating high performance with low average power. System 100 thus provides benefits of clock forwarding and embedded clocking using relatively simple and efficient circuitry.

In one embodiment, transmitter 107 encodes 16-bit data words Daₙ[15:0] of a serial or parallel data signal into parallel first and second data signals Da0[8:0] and Da90[8:0]. Each data signal is composed of a series of 9-bit words or sub-words (e.g. sub-words Da0ₙ[8:0] and Daₙ90[8:0]) that in one embodiment are transmitted with a relative phase offset of 90 degrees. The resulting phase-offset sequences of sub-words are transmitted to IC 110 via respective sub-channels 115 and 120, each of which is a nine-line bus in this embodiment. The buses and other components associated with the two data signals can be physically adjacent, as shown, or the lines can be e.g. interleaved to facilitate delay matching between the data paths. The term “data word,” as used herein, refers to a collection of related bits, and “sub-word” refers to a portion of a word. In alternate embodiments the size of the data bus may be wider or narrower than 16 bits.

Transmitter 107 employs an encoding scheme used in one embodiment to ensure at least one transition within the code word for each successive sub-word on sub-channels 115 and 120. Receivers within IC 110 recover a pair of clock signals RxClk0 and RxClk90 from their respective data signals. The recovered clock signals RxClk0 and RxClk90 are phase offset by 90 degrees due to the similar phase offset between the respective data signals. In one embodiment the clock signal RxClk0 extracted from the first data signal Da0 [8:0] is then used to sample the second data signal Da90 [8:0], and the clock signal RxClk90 extracted from the second data signal Da90 [8:0] is used to sample the first data signal Da90 [8:0].

Transmitter 107 includes two encoders 125 and 130, which receive respective transmit clock signals TxClk0 and TxClk90 from a suitable internal or exterior clock source 132. In one embodiment, clock signals TxClk0 and TxClk90 are phase offset by 90 degrees so that data signals Da0 [8:0] and Da90 [8:0] likewise exhibit phases that are offset by 90 degrees with respect to one another. An embodiment of an 8-bit to 9-bit (8 b/9 b) encoding scheme that encodes data signals across multiple data nodes (e.g., the conductors of the sub-channels) to guarantee a transition for each successive sub-word on sub-channels 115 and 120 is detailed below. A transmit-enable signal TxEnable facilitates disabling of the transmitted coded data stream to facilitate rapid power-down and power-up at the receiver. The operation of signal TxEnable is explained below.

IC 110 includes two receivers RX0 and RX90, each of which includes a clock input node to receive a clock signal for timing the sampling of data on a plurality of data input nodes. The input nodes of each receiver are AC or DC-coupled to a respective sub-channel. For example, receiver RX90 includes nine input nodes coupled to respective data nodes that convey sub-words Da0ₙ[8:0] of data signal Da[8:0] to IC 110. IC 110 additionally includes two clock-extraction circuits ClkExt0 and ClkExt90. Each extraction circuit includes input nodes that are coupled to at least a subset of the data nodes associated with one sub-channel, and is adapted to extract a clock signal from transitions that occur on its input nodes between sub-words. For example, clock extraction circuit ClkExt0 extracts a clock signal RxClk0 from the first four bits Da[8:5] of the 9 bit data signal Da[8:0] conveyed across sub-channel 115. Clock signal RxClk0 alternately transitions high or low between each adjacent pair of sub-words Da0ₙ[8:0]. Because data signal Da[8:0] is phase offset from data signal Da90[8:0] by 90 degrees, the extracted clock signal RxClk0 is likewise offset from sub-words Da90ₙ[8:0] by about 90 degrees. Consequently, the rising and falling edges of clock signal RxClk0 are centered within the symbols that represent sub-words Da90ₙ[8:0]. Clock extraction circuit ClkExt90 likewise extracts a clock signal RxClk90 with rising and falling edges centered within the symbols that represent sub-words Da0ₙ[8:0]. Some embodiments include delay elements 140 to match the delays associated with the clock extraction circuits. Delay elements may be fixed or adjustable, the latter facilitating margin testing and performance optimization.

Receivers RX0 and RX90 each decode respective 9-bit data signals to restore the encoded data to the originally transmitted 8-bit form. For example, receiver RX0 decodes sub-word Da0ₙ[8:0] to recover data Daₙ[7:0], the original input to encoder 125. Finally, the outputs from receivers RX0 and RX90 may be conveyed to some core logic (not shown), the intended recipient of the transmitted data. In a memory system, the core logic might be memory or memory-controller logic, for example.

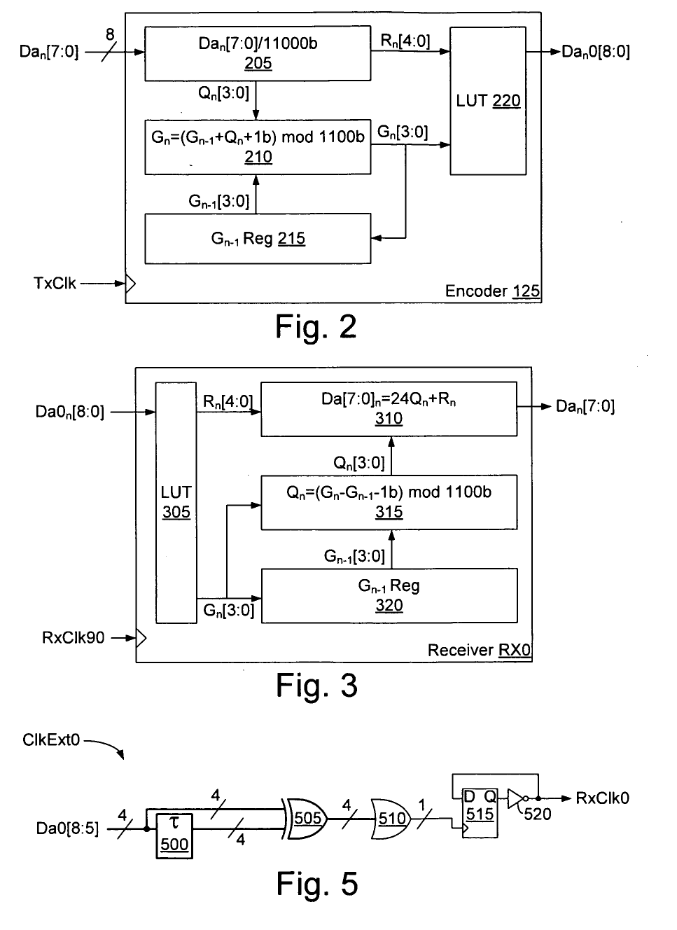

FIG. 2 depicts an embodiment of encoder 125 of FIG. 1, an instance of which may also be used for encoder 130. Encoder 125 can be implemented using synchronous logic timed to a transmit clock signal TxClk to encode 8-bit data into 9-bit codes that ensure a signal transition with which to generate a clock edge between any two successive 8-bit sub-words (e.g., between a current word or sub-word Da0ₙ[8:0] and a subsequent word or sub-word Da0ₙ₊₁[8:0]). Also advantageous, the code words have a narrow range of Hamming weights, so transitioning between code words induces limited supply noise. The following Table 1 illustrates a code space for encoder 125 in accordance with the embodiment of FIG. 2.

TABLE 1

| | | | | HW |
|---|---|---|---|---|
| Group Gₙ[3:0] | Da0ₙ[8:5] | Remainder | Da0ₙ[4:0] | Da0ₙ[8:0] |
| 0 (0000b) | 0 0 0 1 | 0 0 0 0 0 | 24 5-bit codes | 3, 4, 5 |
| 1 (0001b) | 0 0 1 0 | to | HW of 2, 3, 4 | |
| 2 (0010b) | 0 1 0 0 | 1 0 1 1 1 | | |
| 3 (0011b) | 1 0 0 0 | (Zero to 23) | | |
| 4 (0100b) | 0 0 1 1 | 0 0 0 0 0 | 24 5-bit codes | 3, 4, 5 |
| 5 (0101b) | 0 1 1 0 | to | HW of 1, 2, 3 | |
| 6 (0110b) | 1 1 0 0 | 1 0 1 1 1 | (May be the | |
| 7 (0111b) | 1 0 0 1 | (Zero to 23) | inverse of codes | |
| 8 (1000b) | 1 0 1 0 | | for groups 0-3) | |
| 9 (1001b) | 0 1 0 1 | | | |
| 10 (1010b) | 0 1 1 1 | 0 0 0 0 0 | 0 0 0 0 1 | 4, 5 |
| | | 0 0 0 0 1 | 0 0 0 1 0 | |
| | | 0 0 0 1 0 | 0 0 0 1 1 | |
| | | 0 0 0 1 1 | 0 0 1 0 0 | |
| | | 0 0 1 0 0 | 0 0 1 0 1 | |
| | | 0 0 1 0 1 | 0 0 1 1 0 | |
| | | 0 0 1 1 0 | 0 1 0 0 0 | |
| | | 0 0 1 1 1 | 0 1 0 0 1 | |
| | | 0 1 0 0 0 | 0 1 0 1 0 | |
| | | 0 1 0 0 1 | 0 1 1 0 0 | |
| | | 0 1 0 1 0 | 1 0 0 0 0 | |
| | | 0 1 0 1 1 | 1 0 0 0 1 | |
| | | 0 1 1 0 0 | 1 0 0 1 0 | |
| | | 0 1 1 0 1 | 1 0 1 0 0 | |
| | | 0 1 1 1 0 | 1 1 0 0 0 | |
| | 1 0 1 1 | 0 1 1 1 1 | 0 0 0 0 1 | 4, 5 |
| | | 1 0 0 0 0 | 0 0 0 1 0 | |
| | | 1 0 0 0 1 | 0 0 1 0 0 | |
| | | 1 0 0 1 0 | 0 1 0 0 0 | |
| | | 1 0 0 1 1 | 1 0 0 0 0 | |
| | | 1 0 1 0 0 | 0 0 0 1 1 | |
| | | 1 0 1 0 1 | 0 0 1 1 0 | |
| | | 1 0 1 1 0 | 0 1 1 0 0 | |
| | | 1 0 1 1 1 | 1 1 0 0 0 | |
| 11 (1011b) | 1 1 0 1 | Same as | Same as | 4, 5 |
| | | Group 10, | Group 10, | |
| | | Subgroup | Subgroup | |
| | | 0111 | 0111 | |
| | 1 1 1 0 | Same as | Same as | 4, 5 |
| | | Group 10, | Group 10, | |
| | | Subgroup | Subgroup | |
| | | 1011 | 1011 | |

Table 1 divides the code space such that each sub-word Da0ₙ[8:0] of encoded data Da0 [8:0] occupies one of twelve code groups zero to eleven (binary 0000 to 1011, or 0000b to 1011b). The code words are selected such that at least one of bits Da0[8:5] will transition between adjacently transmitted code words, provided code words from one group are not used successively. Encoder 125 guarantees that no two code words from the same group are transmitted successively, so bits Da[8:5] of data signal Da[8:0] are sure to exhibit at least one data transition per symbol time.

In Table 1, each of the first four group numbers 0000b to 0011b (zero to three) has a corresponding code group number, represented by the first four bits Da0ₙ[8:5], that includes a single logic one. The Hamming weight of a binary word is the number of ones contained within the word, so each of the numbers Da0ₙ[8:5] used to specify group numbers 0000b to 0011b has a Hamming weight of one. The remaining five bits of a given code word, Da0ₙ[4:0], is specified using one of twenty-four five-bit numbers with Hamming weights of two, three, or four. There are twenty-five such five-bit numbers, so one is not used. The twenty-four numbers used are mapped one-to-one with the twenty-four binary numbers 00000b to 10111b (zero to twenty-three). For example, the lowest value with a Hamming weight of two, three, or four (i.e., 00011b) can be mapped to the lowest binary number 00000b; the next-higher value with Hamming weight of two, three, or four, (i.e., 00101b) can be mapped to the next highest binary value 00001b, and so on. Because in groups 0000b to 0011b the Hamming weights of bits Da0ₙ[8:5] are all one and the Hamming weights of bits Da0ₙ[4:0] are all two, three, or four, the total Hamming weight for any code words Da0ₙ[8:0] in groups 0000b to 0011b is three, four, or five. Limiting the number of Hamming Weights reduces supply-induced switching noise, and consequently improves circuit performance.

Each of the six group numbers 0100b to 1001b (four to nine) has a corresponding code group number Da0ₙ[8:5] that includes exactly two logic ones. The remaining portion of a given code word, Da0ₙ[4:0], is specified using one of twenty-four five-bit numbers with Hamming weights of one, two, or three. There are twenty-five such numbers, so one is not used. The twenty-four numbers used are mapped one-to-one with the twenty-four binary numbers 00000b to 10111b (zero to twenty-three). Because in groups 0100b to 1001b the Hamming weights of Da0ₙ[8:5] are all two and the Hamming weights of Da0ₙ[4:0] are all one, two, or three, the total Hamming weight for any code words Da0ₙ[8:0] in groups 0100b to 1001b is three, four, or five. Numbers Da0ₙ[4:0] in groups four to nine may be the inverse of the numbers in groups zero to four, and this observation may be used to simplify the logic used to correlate code incoming data sub-words (e.g., Daₙ[7:0] of FIG. 1) and code words Da0ₙ[8:0].

Group number ten (1010b) has two corresponding code group numbers Da0ₙ[8:5], 0111b and 1011b, each of which includes exactly three logic ones. The remaining portion of a given code word, Da0ₙ[4:0], is specified using five-bit numbers with Hamming weights of one or two. The total Hamming weight for any code word Da0ₙ[8:0] in group ten (1010b) is therefore either four or five. In this example, fifteen five-bit numbers with Hamming weights of one or two are used in group 1010b, subgroup 0111b, and nine are used in subgroup 1011b. The available code space in group ten is therefore twenty-four nine-bit code words with Hamming weights of four or five.

Finally, group number eleven (1011b) has two corresponding code group numbers Da0ₙ[8:5], 1101b and 1110b, each of which includes exactly three logic ones. The remaining portion of a given code word, Da0ₙ[4:0], is specified in this example using the same five-bit numbers depicted for group ten. The total Hamming weight for any code words Da0ₙ [8:0] in group eleven (1011b) is therefore either four or five.

The code space provided in Table 1 includes twelve groups of twenty-four code words, for a total of 288 code words. A code word from a group associated with a prior code word is not used, so only eleven groups are available to transmit a given code word. The effective code space is therefore the product of eleven and twenty-four, or 264, which is greater than the 256 combinations required to express all eight-bit binary values. The remaining eight combinations may be used to support additional functionality. In a memory system, for example, a data-mask command can be encoded into one of the remaining combinations. (As is well known, memory controllers can use a data-mask command to instruct a memory device to ignore incoming data.) More generally, N-bit data and the timing information required to sample the data is conveyed economically using N+1 bits.

Returning to FIG. 2, encoder 125 includes a divider 205, group-select logic 210, a group register 215, and a look-up table (LUT) 220. Divider 205 divides each incoming 8-bit sub-word Daₙ[7:0] by 24 (11000b), which provides a 4-bit quotient Qₙ[3:0] and a 5-bit remainder Rₙ[4:0]. Group-select logic 210 then calculates the current 4-bit group number Gₙ[3:0] by incrementing the sum of the quotient Qₙ[3:0] and the preceding group number Gₙ₋₁[3:0] and taking the modulo twelve (mod 1100b) of the result. Register 215 stores the current group number Gₙ[3:0] for the next calculation.

LUT 220 looks up the current code word Da0ₙ[8:0] using the current group number Gₙ[3:0] and remainder Rₙ[4:0]. Considering Table 1 and assuming group number Gₙ[3:0] is 1010b and remainder Rₙ[4:0] is 0000b, then Da[8:5] is 0111b and Da0[4:0] is 00001b, i.e., Da[8:0] is 011100001b, which has a Hamming weight of four. Encoder 125 similarly encodes the entire set of 8-bit binary numbers into 9-bit code words with Hamming weights of three, four, or five. This code space has the advantage of low switching-induced supply noise. Further, although not required for the embodiment of FIG. 1, the code space of encoder 125 provides sufficient transition density to support clock recovery.

FIG. 3 depicts receiver RX0 of FIG. 1 in accordance with one embodiment. Receiver RX0 is a 9 b/8 b decoder, an instance of which may also be used for receiver RX90. Decoder RX90 can be implemented using synchronous logic timed to decode 9-bit codes words or sub-words into 8-bit codes. For example, in the embodiment of FIG. 1, receiver RX0 recovers data Da[7:0] from code words Da0ₙ[8:0] using clock signal RxClk90.

Decoder RX0 includes a LUT 305, multiply and add block 310, a quotient block 315, and a group register 320. LUT 305 performs the inverse function of LUT 220 of FIG. 2, and its operation can be implemented as shown in Table 1. Using the prior example in which the 9-bit code word Da0ₙ[8:0] is 011100001b (i.e., Da0ₙ[8:5] is 0111b and Da0ₙ[4:0] is 00001b), Table 1 provides that group number Gₙ[3:0] is 1010b and remainder Rₙ[4:0] is 00000b. Block 315 calculates quotient Qₙ[3:0] by decrementing the difference between the current and previous group numbers Gₙ[3:0] and Gₙ₋₁[3:0] and taking the modulo twelve (mod 1100b) of the result. Register 320 stores the current group number Gₙ[3:0] for use with the next code word. Finally, block 310 produces the 8-bit output data Daₙ[7:0] by adding the remainder Rₙ[4:0] to the product of twenty-four (11000b) and quotient Qₙ[3:0].

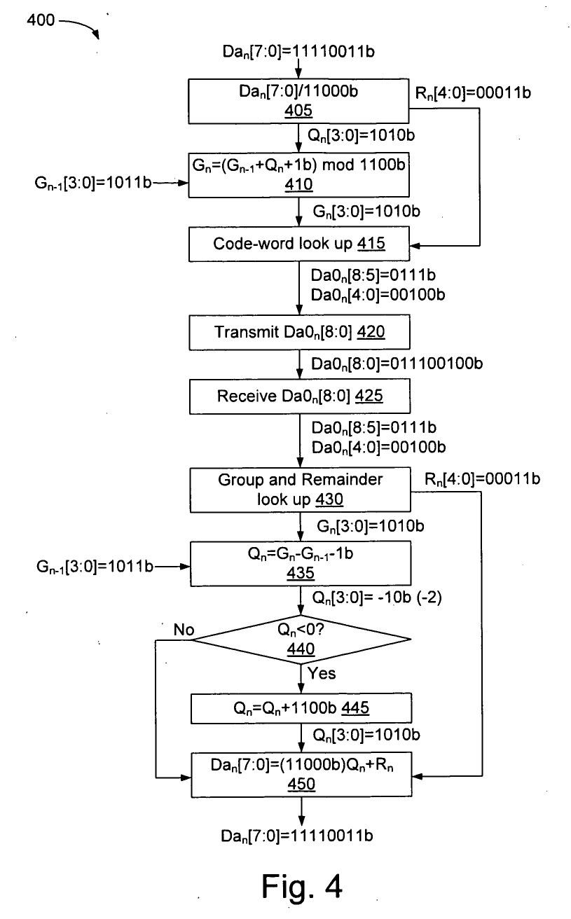

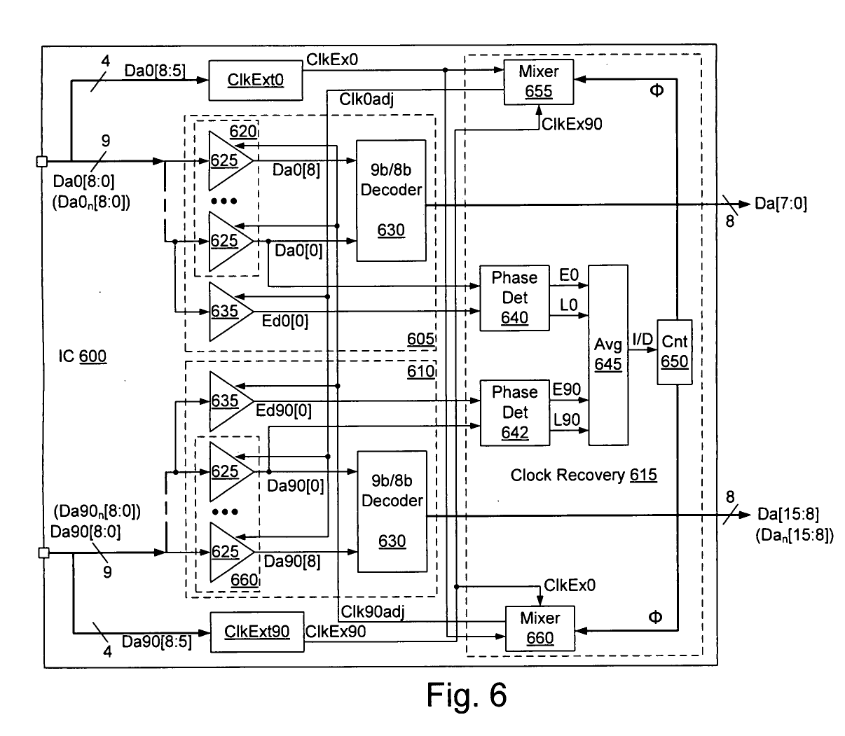

FIG. 4 is a flowchart 400 illustrating the encoding and decoding of an arbitrary sub-word Daₙ[7:0]=11110011b using embodiments of encoder 125 and decoder RX90 of FIGS. 2 and 3, respectively. This example assumes the previous code word Da0ₙ₋₁[8:0] was a member of group number eleven (i.e., Gₙ₋₁=1011b).

Beginning with step 405, sub-word Daₙ[7:0] is divided by 11000b, which gives quotient Qₙ[3:0]=1010b and remainder Rₙ[4:0]=00001b. The quotient Qₙ[3:0] and previous group number Gₙ₋₁[3:0] are then used to calculate the current group number Gₙ[3:0], which comes to 1010b in this example (step 410). There are twelve (1100b) possible group numbers. Step 410 includes a modulo 1100b operation so that the group number calculated in step 410 always falls between zero and eleven, inclusive (i.e., 0000b to 1011b).

With reference to Table 1, the current group number Gₙ[3:0] and remainder Rₙ[4:0] are used to look up the corresponding code word (step 415). In this example, a remainder of 00011b in code group 1010b corresponds to bits Da0ₙ[8:5] of 0111b and bits Da0ₙ[4:0] 00100b, so the code word Da0ₙ[8:0] ultimately transmitted is 011100100b (step 420). Step 420 completes the sequence of encoding and transmission e.g., performed by an embodiment of encoder 125 of FIG. 2.

Decoding begins at step 425 with receipt of code word Da0ₙ[8:0], which in this example consists of bits Da0ₙ[8:5] of 0111b and Da0ₙ[4:0] of 00100b. In the reverse of step 415, and again with reference to Table 1, the code word Da0ₙ[8:0] is used to look up the current group number Gₙ[3:0] and remainder Gₙ[4:0] (step 430). The current and previous group numbers Gₙ[3:0] and Gₙ₋₁[3:0] are then used to calculate the quotient Qₙ[3:0] (step 435). Per decision 440, if quotient Qₙ[3:0] is negative, then 1100b (twelve) is added to quotient Qₙ[3:0]. This reverses the modulo operation of step 410. In the instant example, quotient Qₙ[3:0] from step 435 is negative (−10b, or −2), and so is corrected in step 445 to provide quotient Qₙ[3:0]=1011b. Finally, step 450 reverses step 405 to recover Daₙ[8:0]. In this case quotient Q[3:0] is 1010b and remainder Rₙ[4:0] is 00001b, which recovers the original Daₙ[8:0]=011101100b.

FIG. 5 depicts an embodiment of clock extraction circuit ClkExt0 of FIG. 1, an instantiation of which may also be used for extraction circuit ClkExt90 (with appropriate output and input name changes). The extraction circuit includes a delay element 500, an XOR gate 505, an OR gate 510, a flip-flop 515, and an inverter 520. Delay element 500 and XOR gate 505 each represent four parallel devices, each of which receives a sequence of binary symbols on a respective one of nodes Da0[8:5]. Delay element 500 delays each signal transition by less than one unit interval (e.g., delay time τ may be about ½ of one unit interval). XOR gate 505 only produces logic-one outputs when its input nodes are mismatched, a condition that occurs between the time a signal transition appears on an input of extraction circuit ClkExt0 and when the same transition occurs on the output of delay element 500. XOR gate 505 thus produces a high-going pulse of width responsive to each transition on one of data nodes Da[8:5]. OR gate 510 combines the four outputs from XOR gate 505, and thus produces a high-going pulse of width τ responsive to any one or more transitions on data nodes Da[8:5]. Finally, flip-flop 515 and inverter 520 together cause clock signal RxClk0 to transition responsive to each rising edge from OR gate 510.

The clock extraction circuit of FIG. 5 produces a half-rate clock signal RxClk0, so receiver RX90 uses both rising and falling clock edges to sampling incoming data. The clock extraction circuits can produce clock signals with different rates or duty cycles in other embodiments.

The code space detailed in the foregoing embodiments provides at least one transition on nodes Da[8:5] between code words, so clock signal RxClk0 produces alternating rising and falling clock edges between adjacent code words. Further, because the data transitions for data signal Da[8:5] are offset 90 degrees from the data transitions for data signal Da90[8:0], receiver RX90 can use the rising and falling edges of clock signal RxClk0 to sample data signal Da90[8:0]. Receiver RX0 can likewise use clock signal RxClk90 to sample data signal Da90[8:0]. High-performance signaling is thus facilitated without complex clock extraction circuitry that is difficult to transition through power states. Transmit-enable signal TxEnable (FIG. 1) is de-asserted to power down the clock signals in the receive device. In this embodiment, de-asserting the transmit-enable signal causes the transmitter to transmit constant data, thereby depriving the receiver of transitions from which to recover a clock signal. By not incorporating any transitions between subsequent data words the receive-side will not generate any clock transitions and thus will not consume any switching current whatsoever. This facilitates the rapid turning on and turning off of the data stream, with low or zero power consumption during turn-off periods. These characteristics are particularly important for high-bandwidth, low-power applications. Other methods of embedding and extracting clock signals are well known to those of skill in the art. For example, while the foregoing code is exemplary of a clock-embedded code, alternative codes exist, and these may support more or fewer than eight bits.

FIG. 6 depicts an IC 600 incorporating clock-recovery circuitry in accordance with another embodiment. IC 600 is in some ways similar to IC 110 of FIG. 1, with like-labeled elements being the same or similar. IC 600 recovers clock signals from an eighteen-bit encoded data word that is separated into two parallel data signals Da0[8:0] and Da90[8:0] that are phase offset from one another by e.g. ninety degrees.

IC 600 includes a pair of receivers 605 and 610, clock-extraction circuits ClkExt0 and ClkExt90, and a clock-recovery circuit 615. Receivers 605 and 610 may decode respective data signals Da0[8:0] and Da90[8:0] in the manner detailed above in connection with FIGS. 3 and 4, clock-extraction circuits ClkExt0 and ClkExt90 may extract respective clock signals ClkEx0 and ClkEx90 in the manner detailed above in connection with FIG. 5. Clock-recovery circuit 615 phase adjusts the extracted clock signals ClkEx0 and ClkEx90 to optimize the sample timing for the received data signals. In this embodiment, clock-recovery circuit 615 monitors and continuously adjusts the phase relationship between the incoming data and a pair of phase-adjusted clock signals Clk0adj to and Clk90adj to accommodate timing errors the might otherwise result from e.g. differences between the clock and data path delays, process variations, and supply-voltage and temperature fluctuations.

In one embodiment receiver 605 includes a nine-bit data sampler 620, each input terminal of which is coupled to one of the nine lines that conveys data signal Da0[8:0]. While most of the nine internal data samplers 625 are omitted for clarity, the two shown recover signals Da0[8] and Da0[0] by sampling corresponding signals on edges of an adjusted clock signal Clk90adj, the genesis of which is detailed below. A decoder 630 decodes the resulting sampled data signals Da0[8:0], possibly in the manner described above in connection with Table 1, to recover eight-bit data signal Da[7:0].

Receiver 605 additionally includes an edge sampler 635 that samples data signal Da0[0] on edges of a second adjusted clock signal Clk90adj that is at or about ninety degrees out of phase with respect to the other adjusted clock signal Clk0adj. Due to this phase shift, edge sampler 635 samples data signal Da0[0] at or near the Da0[0] data transitions, or edges, to provide a sampled-edge signal Ed0[0]. Other data signals or collections of data signals may be edge-sampled in other embodiments to derive a sampled-edge signal. Receiver 610 is functionally similar to receiver 605, with like-labeled elements being the same or similar. A detailed discussion of receiver 610 is omitted for brevity.

Clock recovery circuitry 615 includes a pair of bang-bang (Alexander) phase detectors 640 and 642 and, in one embodiment, the components of a CDR-loop consisting of averaging logic 645, a counter 650, and a pair of phase mixers (or interpolators) 655 and 660. Phase detector 640 compares the current edge sample Ed0[0]ₙ with the current and prior data samples Da0[0]ₙ and Da0[0]ₙ₋₁ to determine whether the edge between the current and prior data samples is early or late with respect to the corresponding edge of clock signal Clk0adj. Alexander phase detectors are well known to those of skill in the art, so a detailed discussion is omitted. Briefly, samples Da[0]ₙ and Da0[0]ₙ₋₁ are one bit period (one unit interval) apart and edge sample Ed0[0]ₙ is sampled at half the bit period between samples Da0[0]ₙ and Da0[0]ₙ₋₁. If the current and prior samples Da0[0]ₙ and Da0[0]ₙ₋₁ are the same (e.g., both represent logic one), then no transition has occurred and there is no “edge” to detect. In that case, the early and late outputs E0 and L0 from phase detector 640 are both zero. If the current and prior samples Da0[0]ₙ and Da0[0]ₙ₋₁, are different, however, then the edge sample Ed0[0]ₙ is compared with the current and prior samples Da0[0]ₙ and Da0[]ₙ₋₁: if edge sample Ed0[0]ₙ equals prior data sample Da0[0]ₙ₋₁, then late signal L0 is asserted (the data is late relative to the clock edge); and if edge sample Ed0[0]ₙ equals current sample Da0[0]ₙ, then the early signal E0 is asserted.

Phase detector 642 compares a second edge sample Ed90[0]ₙ with the current and prior data samples Da90[0]ₙ and Da90[0]ₙ₋₁ to determine whether the edge between the current and prior data samples is early or late with respect to the corresponding edge of clock signal Clk0adj. Phase detector 642, based upon this comparison, produces early and late signals E90 and L90 in the manner discussed above in connection with phase detector 640. Other embodiments omit phase detector 642.

Averaging logic 645, which acts as a low-pass filter, increments or decrements counter 650 in response to accumulated early or late signals. Counter 650 thus accumulates a phase control signal Φ that is passed to mixers 655 and 660. Mixer 655 derives clock signal Clk0adj by combining extracted clock signals ClkEx0 and ClkEx90 responsive to phase control signal Φ. The feedback provided by clock recovery circuit 615 thus locks clock signal Clk0adj to edges of data signal Da0[0]. Mixer 660 works the same way as mixer 655, but the sense of the mixed clock signals ClkEx0 and ClkEx90 are swapped so that the phase adjustments track between mixers 655 and 660 responsive to the same phase control signal Φ.

As noted previously, data signals Da0[8:0] are ninety-degrees output of phase with respect to data signals Da90[8:0]. Locking clock signal Clk0adj to transitions of data signal Da0[8:0] and clock signal Clk90adj to transitions of data signal Da90[8:0] thus fixes the rising and falling edges of clock signals Clk0adj and Clk90adj to the centers of the data eyes associated with respective data signals Da90[8:0] and Da0[8:0]. The phase-adjusted clock signals Clk0adj and Clk90adj can therefore be used by receivers 610 and 605 to sample respective data signals Da90[8:0] and Da0[8:0].

In other embodiments, counter 650 can be provided with a different or additional control signal to phase adjust clock signals ClkEx0adj and ClkEx90adj based upon some measure of merit, such as the bit-error rate of the data signals. Still other embodiments omit one or both samplers. An advantage to the foregoing circuits is that they do not waste power distributing a receive clock absent incoming data. To take full advantage of this benefit, clock-recovery circuits 615 and 617 should be designed to use little or no power absent incoming data. This can be achieved by minimizing or eliminating the use of any class-“A” analog amplifiers or other analog circuits that consume continuous power.

Other embodiments may support other methods of extracting clock signals from the data. In a serial link, for example, a clock signal may be conveyed with the data as a sub-channel or common-mode signal. Phase-offset clock signals could thus be extracted from a pair of serial links to sample the data from each link using the clock signal from the other. Furthermore, while the data and clock phase offsets are described as being 90 degrees, any phase offset that places the sampling points within the data eyes of a sampled data symbol may work. Phase offsets of 90 degrees should therefore be interpreted to include some tolerance about 90 degrees. The 90-degree phase shifts are measured between nearest edges of data signals, and not between corresponding symbols. A phase shift of 450 degrees (360+90) is therefore considered to be a 90-degree phase shift.

An output of a process for designing an integrated circuit, or a portion of an integrated circuit, comprising one or more of the circuits described herein may be a computer-readable medium such as, for example, a magnetic tape or an optical or magnetic disk. The computer-readable medium may be encoded with data structures or other information describing circuitry that may be physically instantiated as an integrated circuit or portion of an integrated circuit. Although various formats may be used for such encoding, these data structures are commonly written in Caltech Intermediate Format (CIF), Calma GDS II Stream Format (GDSII), or Electronic Design Interchange Format (EDIF). Those of skill in the art of integrated circuit design can develop such data structures from schematic diagrams of the type detailed above and the corresponding descriptions and encode the data structures on computer readable medium. Those of skill in the art of integrated circuit fabrication can use such encoded data to fabricate integrated circuits comprising one or more of the circuits described herein.

In the foregoing description and in the accompanying drawings, specific terminology and drawing symbols are set forth to provide a thorough understanding of the foregoing embodiments. In some instances, the terminology and symbols may imply specific details that are not required to practice the invention. For example, the encoder and decoder depicted in respective FIGS. 2 and 3 may be modified for improved performance, reduced power consumption, or reduced area. For example, the logic performed by the various logic blocks and LUTs could be optimized using techniques well understood by those of skill in the art. Similarly, signals described or depicted as having active-high or active-low logic levels may have opposite logic levels in alternative embodiments. Furthermore, the term “system” may refer to a complete communication system, including a transmitter and a receiver, or may refer to portion of a communication system, such as a transmitter, a receiver, or an IC or other component that includes a transmitter and/or receiver. Still other embodiments will be evident to those of skill in the art.

Some components are shown directly connected to one another while others are shown connected via intermediate components. In each instance the method of interconnection, or “coupling,” establishes some desired electrical communication between two or more circuit nodes (e.g., pads, lines, or terminals). Such coupling may often be accomplished using a number of circuit configurations, as will be understood by those of skill in the art. Therefore, the spirit and scope of the appended claims should not be limited to the foregoing description. Only those claims specifically reciting “means for” or “step for” should be construed in the manner required under the sixth paragraph of 35 U.S.C. §112.

What is claimed is:

1. A system comprising:
a first receiver to receive a first data signal exhibiting a first phase;
a first clock-extraction circuit to extract a first clock signal from at least a portion of the first data signal; and
a second receiver to sample a second data signal, exhibiting a second phase different from the first phase, with the first clock signal.

2. The system of claim 1, further comprising a second clock-extraction circuit to extract a second clock signal from at least a portion of the second data signal, wherein the first receiver samples the first data signal with the second clock signal.

3. The system of claim 1, wherein the second receiver has N+1 receiver input nodes, wherein N is at least one.

4. The system of claim 3, wherein the second receiver includes N output nodes.

5. The system of claim 4, wherein N is eight.

6. The system of claim 1, wherein the first and second data phases are offset by ninety degrees.

7. The system of claim 1, wherein the first-receiver includes N input nodes to receive the first data signal, and wherein the first-extraction-circuit includes fewer than N data nodes.

8. The system of claim 1, further comprising a first encoder having a first encoder clock terminal, to receive a first clock signal of a first clock phase, and at least one first-encoder output node coupled to the first receiver to transmit the first data signal.

9. The system of claim 8, further comprising a second encoder having a second encoder clock terminal, to receive a second clock signal of a second clock phase different from the first clock phase, and at least one second-encoder output node coupled to the second receiver to transmit the second data signal.

10. The system of claim 8, wherein the first encoder encodes first N-bit data to provide the first data signal, and wherein the first receiver has N+1 first-receiver input nodes to receive the first data signal.

11. The system of claim 10, wherein the second encoder encodes second N-bit data to provide the second data signal, and wherein the second receiver has N+1 second-receiver input nodes to receive the second data signal.

12. The system of claim 1, wherein the first data signal is encoded in a coding space having at least 2^{N} N+1-bit code words.

13. The system of claim 12, wherein each code word has a Hamming weight, and wherein the number of distinct Hamming weights for the code words is less than (N+1)/2.

14. The system of claim 13, wherein the distinct Hamming weights are consecutive integers.

15. A method comprising:
receiving first and second data signals;
extracting a first clock signal from the first data signal and a second clock signal from the second data signal; and
sampling the first data signal using the second clock signal and the second data signal with the first clock signal.

16. The method of claim 15, wherein the first and second data signals are phase offset with respect to one another.

17. The method of claim 16, wherein the phase offset is about ninety degrees.

18. The method of claim 15, wherein the first data signal includes N+1 parallel symbols.

19. The method of claim 18, wherein the first clock signal is extracted from less than N of the parallel symbols.

20. The method of claim 18, further comprising decoding the first data signal to N-bit data.

21. A method comprising:
separating data into first and second sub-data;
encoding the first sub-data into a first data signal of a first phase;
encoding the second sub-data into a second data signal of a second phase different from the first phase; and
transmitting the first data signal and the second data signal over respective first and second sub-channels.

22. The method of claim 21, wherein the first and second data signals are offset by about ninety degrees.

23. The method of claim 21, wherein the first sub-data is N-bit data, and wherein the first data signal comprises N+1 parallel symbols.

24. A computer-readable medium having stored thereon a data structure defining at least a portion of an integrated circuit, the data structure comprising:
first data representing a first receiver having at least one first-receiver input node, to receive a first data signal exhibiting a first phase;
second data representing a second receiver having at least one second-receiver input node, to receive a second data signal exhibiting a second phase, and a second-receiver clock input node; and
third data representing a first clock-extraction circuit having at least one first-extraction-circuit input node, coupled to the at least one first-receiver input node, and a first clock output node coupled to the second clock input node.

25. An integrated circuit comprising:
first and second data ports to receive respective first and second data signals;
means for extracting a first clock signal from the first data signal and a second clock signal from the second data signal, and for sampling the first data signal using the second clock signal and the second data signal with the first clock signal.

26. A transmitter comprising:
a data bus to convey a data signal as a sequence of data words, each data word including a first sub-word and a second sub-word;
a first encoder to encode the sequence of first sub-words, of a first phase, and to embed first timing information in the sequence of first sub-words; and
a second encoder to encode the sequence of second sub-words, of a second phase different from the first phase, and to embed second timing information in to the sequence of second sub-words.

27. The transmitter of claim 26, wherein the first encoder selects each of the first sub-words from a code space that ensures at least one signal transition between each pair of adjacent first sub-words.

28. The transmitter of claim 27, wherein the second encoder selects each of the second sub-words from the code space.

29. The transmitter of claim 26, wherein the sequence of first sub-words is phase offset from the sequence of second sub-words by about 90 degrees.

30. The transmitter of claim 26, wherein each of the first sub-word is N bits, and each first sub-word with embedded first timing information is N+1 bits.
